(19) United States
(12) Patent Application Publication
(10) Pub. No.: US 2019/0385890 A1
(43) Pub. Date: Dec. 19, 2019

(54) APPARATUS FOR SUPPORTING AND MANEUVERING WAFERS

(71) Applicant: Veeco Precision Surface Processing LLC, Horsham, PA (US)

(72) Inventors: William Gilbert Breingan, Horsham, PA (US); Herman Itzkowitz, Horsham, PA (US)

(21) Appl. No.: 16/441,873

(22) Filed: Jun. 14, 2019

Related U.S. Application Data
(60) Provisional application No. 62/686,494, filed on Jun. 18, 2018.

(51) Int. Cl. H01L 21/683; H01L 21/677

(52) U.S. Cl. CPC H01L 21/6838; H01L 21/67742

(57) ABSTRACT

An apparatus for supporting and maneuvering a wafer comprises a handle having a gas inlet adapted to couple to a gas supply, a supporting surface coupled to the handle section including a frame structure having edge segments connecting at vertices and spoke elements extending from a center of the frame structure to the vertices, a gas supply channel coupled to the gas inlet that extends from the handle and branches into channels that run through the spoke elements, and a plurality of nozzles positioned at the vertices on the supporting surface and coupled to the channels in the spoke elements. Gas provided to the plurality of nozzles exits the nozzles in a stream directed parallel to the supporting surface and the stream of gas generates forces that enable wafers to be securely supported in a floating manner over the supporting surface without coming into direct contact with the supporting surface.

### CROSS REFERENCE TO RELATED APPLICATION

The present invention claims priority to and the benefit of US patent application Ser. No. 62/686,494, filed Jun. 18, 2018, which is hereby incorporated by reference in its entirety.

### FIELD OF THE INVENTION

The present invention relates to semiconductor fabrication equipment, and in particular, relates to an apparatus for supporting and maneuvering (transporting) wafers between a plurality of wafer processing stations in an automated manner.

### BACKGROUND OF THE INVENTION

In the fabrication of semiconductor devices, IC wafers, which typically take the form of flat disks made from silicon, gallium arsenide or other materials, may be processed using various chemicals. During the fabrication process, the wafers are often thinned to expose interconnect pads to provide fan-out wafer level packaging (FOWLP). One promising technique for thinning is single wafer wet etching, in which wafers are immersed in one or more etchants, then cleaned and dried. Each of these steps in the fabrication process occurs within a separate station within a wet etching processing system. The wafers, being thin and sensitive to slight damage, must be transferred between the stations with great care.

Processing systems typically employ a robot arm that can swivel, pivot and/or translate from one station to another within the processing system. The robot arms may be equipped with grippers and vacuum suction to secure wafers from shifting horizontally or vertically during transfers between stations. However, one drawback of using conventional vacuum suction to secure wafers is that the suction forces the wafer surface into contact with the supporting surface on the robot arm, which can potentially damage components on the wafer surface.

It would therefore be advantageous to provide a robot arm support for wafer transfers that avoids undue forcible contact with wafer surfaces.

It is with respect to these and other considerations that the disclosure made herein is presented.

### SUMMARY OF THE INVENTION

Embodiments of the present invention provide an apparatus for supporting and maneuvering a wafer. The apparatus comprises a handle section including a gas inlet adapted to couple to a gas supply, a supporting surface coupled and adjacent to the handle section including a frame structure having a plurality of edge segments connecting to one another at vertices and a plurality of spoke elements extending from a center of the frame structure to the vertices, a gas supply channel coupled to the gas inlet that extends from the handle and branches into channels that run through the plurality of spoke elements, and a plurality of nozzles positioned at the vertices on the supporting surface and coupled to the gas supply channel via the channels in the spoke elements. Gas provided to the plurality of nozzles exits the nozzles in a high-speed stream directed parallel to the supporting surface, and the stream of gas generates attractive and repulsive forces enabling a wafer to be securely supported in a floating manner over the supporting surface without coming into direct contact with the supporting surface or the plurality of nozzles.

In some embodiments, the apparatus further comprises a vacuum check port positioned in the handle and a vacuum check circuit that extends from the vacuum check port through the edge segments of the supporting surface frame structure to the plurality of nozzles, wherein the vacuum check circuit enables detection of whether a wafer is being supported by the supporting surface. The apparatus can also include at least one restraining device adapted to prevent a supported wafer from moving in a plane parallel to the supporting surface. In some implementations, the restraining device includes movable grippers coupled to the handle and stationary retainers coupled to an end of the supporting surface.

The gas supply preferably provides a supply of nitrogen gas. In certain embodiments, each of the plurality of nozzles includes an annular top plate joined at an inner rim to a bottom plate, the bottom plate having a set of holes coupled to a respective spoke channel that are configured to force supplied gas through an interface between the outer rim of the top plate and the bottom plate.

Embodiments of the present invention also provide a system for supporting and maneuvering a wafer. The system comprises an apparatus for supporting and maneuvering the wafer that includes a handle section including a gas inlet adapted to couple to a gas supply, a supporting surface coupled and adjacent to the handle section including a frame structure having a plurality of edge segments connecting to one another at vertices and a plurality of spoke elements extending from a center of the frame structure to the vertices, a gas supply channel coupled to the gas inlet that extends from the handle and branches into channels that run through the plurality of spoke elements, and a plurality of nozzles positioned at the vertices on the supporting surface and coupled to the gas supply channel via the channels in the spoke elements, the plurality of nozzles providing a high speed stream directed parallel to the supporting surface. The system further includes a control sub-system positioned between the gas supply and the apparatus and adapted to regulate a pressure supplied to the apparatus based on a size of the wafer.

In some embodiments the control sub-system includes a pressure sensor coupled to the gas supply and adapted to determine a current gas pressure of the gas supply and an electronic pressure regulator coupled to the pressure sensor and adapted to receive pressure data from the pressure sensor and to modify the pressure of gas received from the gas supply based on the pressure data and the size of the wafer to be supported. Implementations of the control sub-system can also include a filter positioned downstream from the electronic pressure regulator for removing impurities from the gas supply before the gas reaches the apparatus. The gas supply of the system preferably provides a supply of nitrogen gas.

These and other aspects, features, and advantages can be appreciated from the following description of certain embodiments of the invention and the accompanying drawing figures and claims.

### BRIEF DESCRIPTION OF THE DRAWINGS

FIG. 1 is a top plan view of an apparatus for supporting and maneuvering a wafer according to an embodiment of the present invention.

FIG. 2 is the top plan view of the apparatus shown in FIG.1 as shown supporting a wafer.

FIG. 3 is a bottom view of the apparatus.

FIG. 4 is a cross-sectional view of the apparatus taken along axis A-A shown in FIG.1.

FIG. 5 is top view of a Bernoulli nozzle according to an embodiment of the present invention.

FIG. 6 is a cross-sectional view of the embodiment of the Bernoulli nozzle along axis B-B shown in FIG. 5.

FIG. 7 is a bottom view of the embodiment of the Bernoulli nozzle of FIGS. 5 and 6.

FIG. 8 is a cross-sectional view taken along part of axis C-C of FIG. 2.

FIG. 9 is a block diagram of a system for regulating nitrogen pressure supplied to the apparatus for supporting and maneuvering wafers according to an embodiment of the present invention.

### DETAILED DESCRIPTION OF CERTAIN EMBODIMENTS OF THE INVENTION

Embodiments of the present invention provide an apparatus for supporting and maneuvering wafers that is shaped in the form of a paddle and configured to transport a wafer between processing stations. The paddle includes one or more nozzles, referred to as “Bernoulli nozzles”, that generate a lateral flow of high speed gas, such as nitrogen (N2). The high-speed gas flow creates a low-pressure region in the vicinity of the gas flow according to the well-known Bernoulli equation. The low-pressure region, in turn, generates a lift force that attracts objects toward the nozzles. In addition, in some embodiments, the apparatus includes mounts for the one or more nozzles that have walls higher than the nozzle surfaces. This mount configuration forces the flow of gas exiting the nozzles through a narrow gap which creates a countervailing repulsive force in the opposite direction of the lift, away from the nozzles. With suitable control of gas pressure and mount design, the opposing attractive and repulsive forces can be set to balance one another, enabling a wafer to be supported at a distance from the nozzle in a floating manner, avoiding contact between the wafer and the surface of the nozzles on the paddle. Advantageously, the balance of attractive and repulsive forces produced by the gas flow can maintain the wafer in place relative to the supporting surface when the wafer is positioned on top of the paddle surface, in an upside-down arrangement in which the wafer is positioned below the paddle, and at oblique angles in between. Thereby, the paddle can be turned while still supporting a wafer, enabling the wafer to be flipped for two-sided processing.

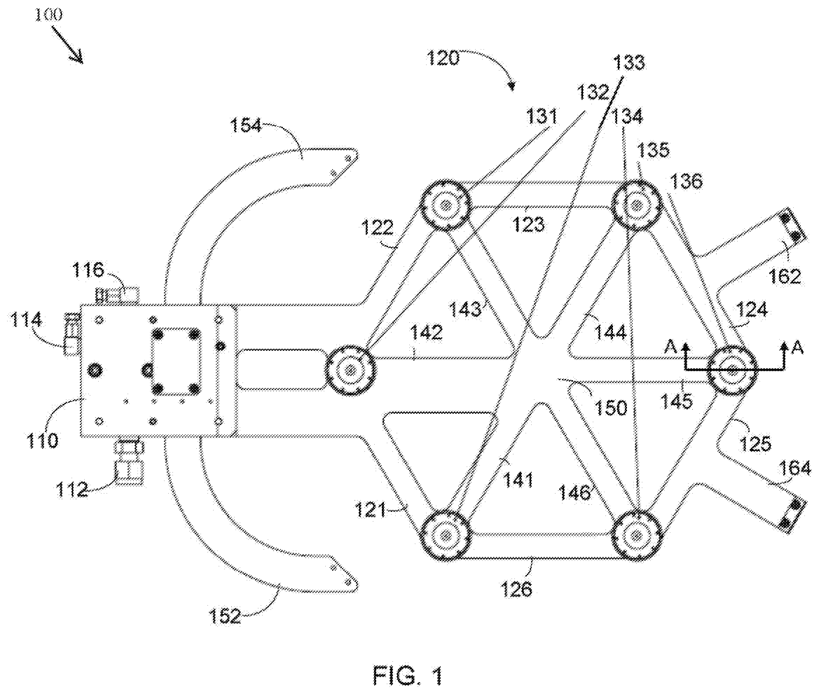

FIG. 1 shows a top plan view of an apparatus 100 for supporting and maneuvering a wafer according to an embodiment of the present invention. The apparatus 100 is formed in the manner of a paddle, with a proximal handle section 110 and a distal supporting surface section 120 adapted for securely supporting a wafer without direct contact. The handle 110 comprises a gas intake manifold and includes a first gas inlet 112 for the supply of a gas, preferably nitrogen (N₂), to the apparatus, an air inlet 114, and a vacuum check port 116. In the depicted embodiment, the supporting surface 120 is hexagonal in shape and comprises a frame structure with edge segments, e.g., 121, 122, 123, 124, 125, 126 that meet at vertices 131, 132, 133, 134, 135, 136. Additionally, spoke elements 141, 142, 143, 144, 145, 146 extend from a center (hub) 150 of the paddle to each of the vertices 131-136. Two arcing moveable grippers 152, 154 are coupled to the lateral sides of the handle 110. Moveable grippers 152, 154 can be actuated pneumatically to move longitudinally toward or away from the supporting surface 120 via pressurized air provided through air inlet 114. The grippers 152, 154 move in unison as the applied air causes extension of grippers 152, 154 toward section 120. In addition, the supporting surface 120 includes stationary retainers 162, 164 that extend outwardly from respective edges 125, 126 of the paddle. The combination of the moveable grippers 152, 154 and stationary retainers 162, 164 keeps wafers placed on the surface of the paddle frame from shifting laterally (horizontally) or vertically on supporting surface 120.

In the depicted embodiment, each of the vertices 131-136 of the supporting surface include a mount for receiving a Bernoulli nozzle as described further below. The overall sizes and dimensions of the apparatus 100 and its components are designed to accommodate a standard-sized semiconductor circular wafer of a diameter such as 200, 300 or 450 mm. It is to be appreciated however that the apparatus can be adapted for smaller or larger-sized wafers.

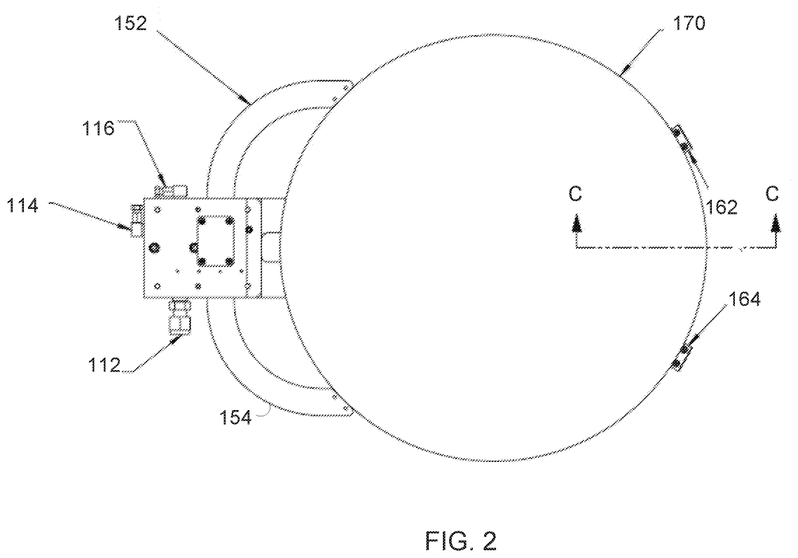

FIG. 2 is a top plan view showing a circular wafer 170 used for semiconductor fabrication positioned on the supporting surface 120. As shown, the ends of movable grippers 152, 154 are in contact with the circumference of the wafer on the proximal side of the wafer, and the retainers 162, 164 are in contact with the circumference of the wafer at a distal side.

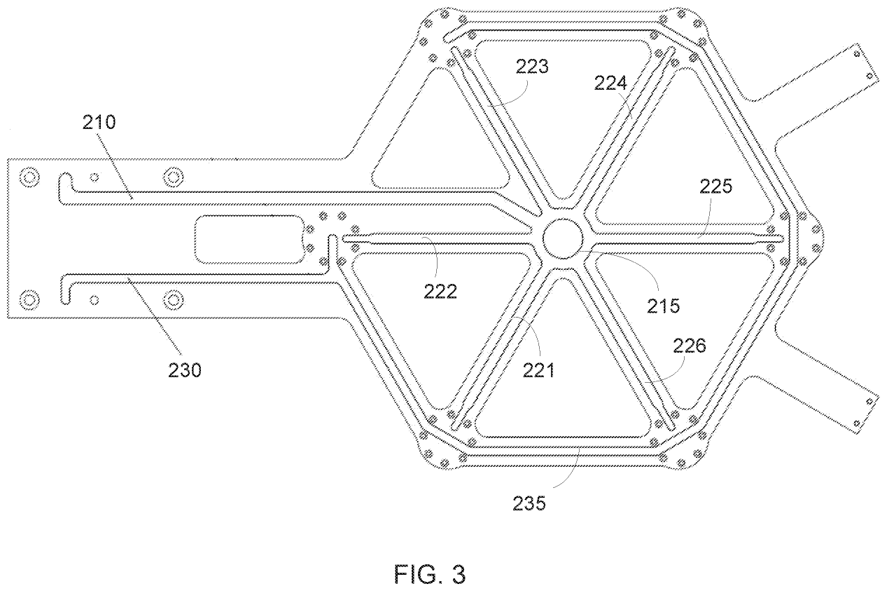

FIG. 3 is a bottom view of the apparatus that depicts channels through which nitrogen gas is supplied to the supporting surface as well as a vacuum check circuit. Longitudinal nitrogen supply channel 210 extends from the gas inlet 112 (FIG. 1) within the handle 110 toward the center hub of the supporting surface 120 where the channel enters an annular conduit 215 positioned around the center 150 (FIG. 1). From the annular conduit 215, a series of spoke channels 221, 222, 223, 224, 225, 226 emerge and extend along the respective spoke elements 141, 142, 143, 144, 145, 146 of frame of supporting surface 120. In this arrangement, a supply nitrogen gas can be provided to all the vertices 131, 132, 133, 134, 135, 136 of the supporting surface. This allows for equal gas flow to each nozzle. In addition, a vacuum check circuit includes a longitudinal vacuum check channel 230 that extends from the vacuum check port 116 in the handle 110 to the supporting surface 120 where it takes a circumferential path 235 through several of the edges 121, 123, 124, 125, 126 of the supporting surface. As explained further below, the vacuum check circuit can be used to establish whether a wafer is positioned in near contact with the support surface because the presence or absence of a wafer has a readily measurable effect on the pressure within the vacuum check circuit. It will be appreciated that a cover is disposed over the nitrogen supply channel 210 and vacuum check channel 230 and can be attached to the other body structure using conventional techniques, such as welding/bonding.

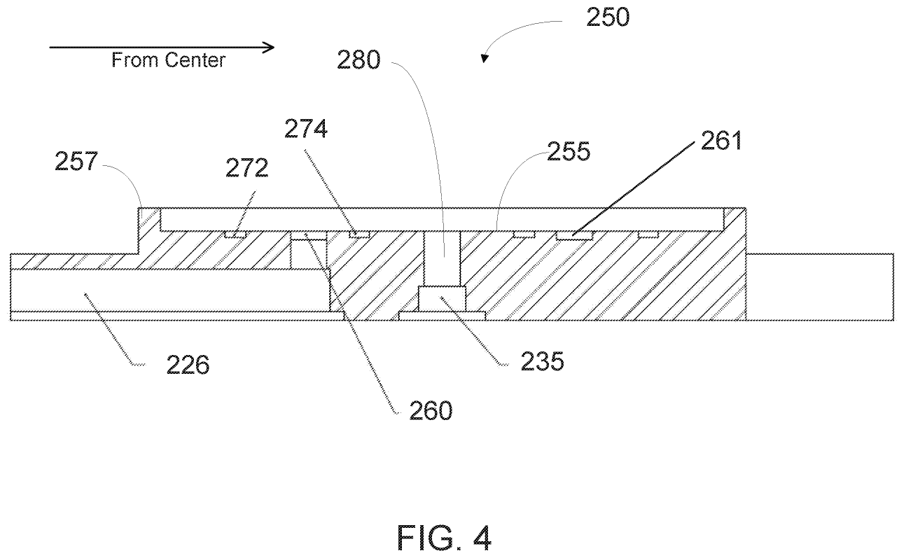

Referring now to FIG. 4, a cross-sectional view taken along axis A-A of FIG. 1 is shown and it will be understood that the other vertices have same or similar construction in that there is a mount at each vertex so as to locate 1 nozzle at each vertex. The view of FIG. 4 shows a mount 250 for receiving a Bernoulli nozzle according to an embodiment of the present invention. A side of the mount 250 that is positioned relatively toward the center of the supporting structure contains the nitrogen spoke channel 226 adapted to supply gas to the mount at vertex 134. A vertical nitrogen supply plenum 260 extends from the end of spoke channel 226 to a top surface 255 which is circumscribed by a flange 257. As shown in FIG. 4, the vertical supply plenum 260 has a vertical component formed vertically within the body of the mount 250 but also at a top of the vertical component, there is a supply channel 261 that is in fluid communication with the vertical component and is open along the mount top surface 255. The supply channel 261 that is in fluid communication with the vertical supply plenum 260 can have a circular shape and thus gas that flows through one of the spoke channels flows into the single plenum 260 located at one mount and is then distributed along the circular path of the supply channel 261 to permit gas distribution in an annular shaped pattern to the underside of the nozzle. The flange 257 can be higher than the top 155. Nitrogen supply plenum 260 thereby provides nitrogen gas directly to the mount top surface 255. The top surface can include a plurality of O-ring grooves, e.g., 272, 274, for receiving corresponding O-rings of a Bernoulli nozzle. The circumferential vacuum check channel 235 runs through the center of the mount 250. A vertical check channel 280 leads from the vacuum check channel 23 to the mount top surface 255. The vertical check channel 280 remains open after a Bernoulli nozzle is installed in the mount 250, enabling the detection of the presence or absence of a wafer through pressure differences. The mount 250 can also include screw holes (not shown) for receiving screw fasteners for securing a Bernoulli nozzle to the mount.

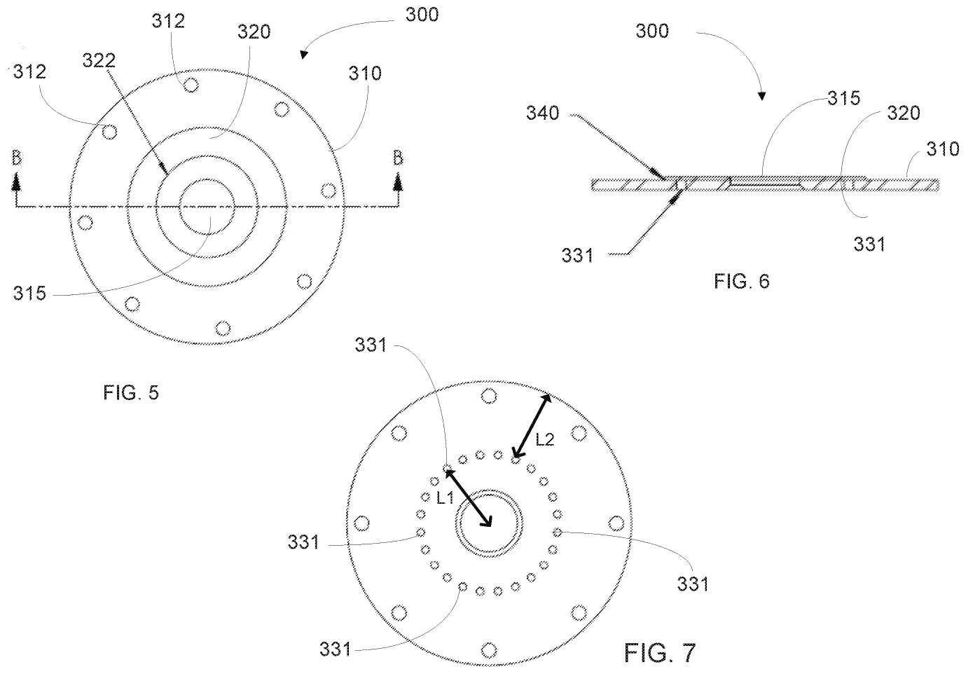

FIGS. 5-7 are top, cross-sectional and bottom views of an exemplary Bernoulli nozzle that can be mounted and installed in the wafer supporting and maneuvering apparatus according to an embodiment of the present invention. Referring to FIG. 5, a Bernoulli nozzle 300 is comprised of a bottom plate 310, and a top plate 320 coupled one atop the other concentrically. In the depicted embodiment, bottom plate 310 is circular in form and includes a central hole 315 and similarly, the top plate 320 has a central hole that is in registration with central hole 315 when the two plates are joined. The top plate 320 is annular in form and has an outer diameter substantially smaller than the outer diameter of the bottom plate 310. The outer diameter of top plate 320 can be, for example, about 40-60 percent of the diameter of the bottom plate as measured from the center of the nozzle, and the inner diameter of the top plate 320 can be about 25-35% percent of the diameter of the bottom plate, but other sizes can be used. Screw holes e, g. 312 are positioned around the outer rim of the bottom plate for enabling the nozzle 300 to be fastened to the mount 250 on the supporting surface. In some implementations, the top plate 320 is coupled to the bottom plate 310 by welding, for example by welding the top plate 320 to the bottom plate 310 along a circle in the middle of the top plate (keyhole weld). It will be appreciated that the above values are only exemplary and not limiting of the present invention and therefore, other values outside of the exemplary ranges are equally possible.

Turning now to the cross-sectional view of FIG. 6, nitrogen gas exit holes 331 extend through the width of bottom plate 310 directly beneath top plate 320. The nitrogen gas exit holes 331 are arranged in a circular pattern and are positioned a predetermined distance from the outer edge of the top plate 320 when the two plates 310, 320 are joined. At the interface 340 between the outer rim of the top plate 320 and the bottom plate 310, the plates appear to be firmly joined together without a gap. For example, a bond is formed between the plates and in one embodiment, the plates 310, 320 are welded to one another. However, it is possible, during operation, for a narrow, high-velocity stream of nitrogen gas to force its way through the interface (bond) between the two plates 310, 320. The gas stream enters through gas exit holes 331 in the bottom plate 310 and then exits horizontally (radially) along the surface of the bottom plate 310 and is directed toward the outer circumference of the plate, thereby generating a lateral fluid flow. The bottom view of FIG. 7 shows the inlet of nitrogen gas exit holes 331 arranged in the circular pattern around central hole 315. The exit holes 331 are positioned a distance L1 from the center and a distance L2 from the circumference of bottom plate 310. The size of the exit holes 331 can vary depending upon the application. The holes 331 are thus positioned so that they overlie the annular shaped supply channel 261 that receives gas from the plenum 260 and therefore, gas flowing within the annular shaped supply channel 261 flows into the holes 331 along the underside of the bottom plate 310 for distribution of the gas.

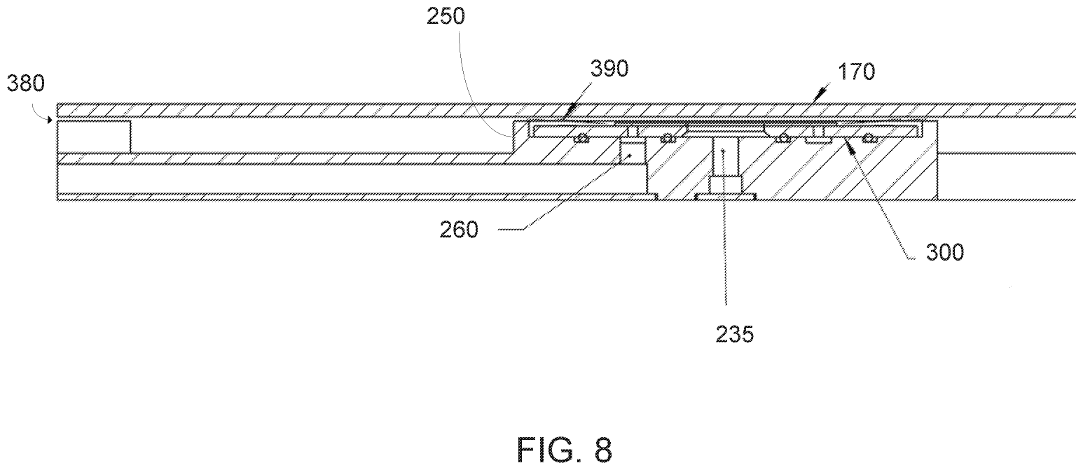

FIG. 8 is a cross-sectional view taken along part of axis C-C of FIG. 2. This view shows a Bernoulli nozzle 300 installed in a mount 250 on the supporting surface, fed by the nitrogen supply plenum 260. A wafer 170 is shown floating a small gap distance 380 above the supporting surface due to the radial (lateral) Bernoulli gas flow 390 that exits from Bernoulli nozzle 300. As shown in FIG. 8, the wafer 170 is in direct fluid communication with vacuum check port 235 to allow for the presence of the wafer 170 to detected in the manner described herein.

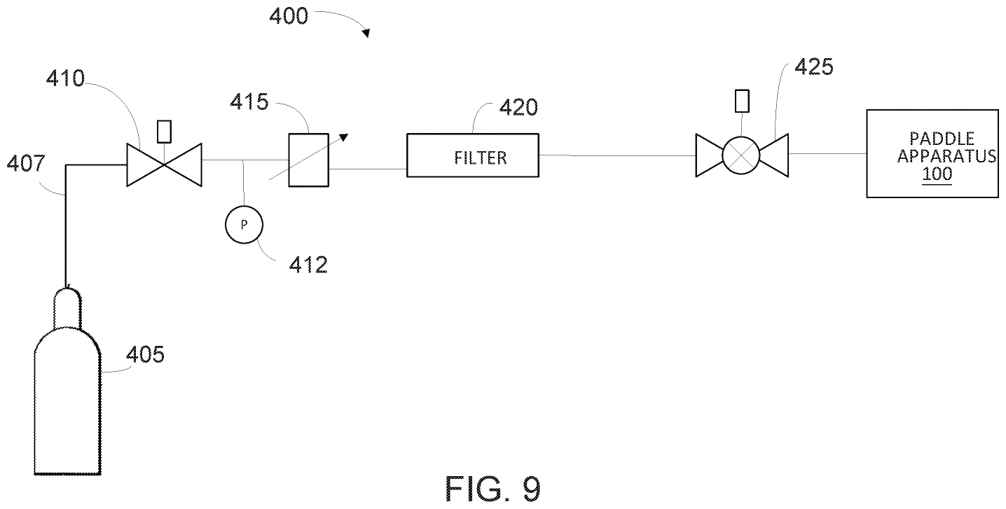

FIG. 9 depicts a control system 400 for controlling nitrogen gas pressure provided to the apparatus for securing and maneuvering wafers according to an embodiment of the present invention. A nitrogen gas supply 405 is coupled to a gas supply line 407 for delivering gas to the paddle apparatus 100. A manual shut-off valve 410 positioned directly downstream of the nitrogen supply can be used to turn on or shut off the gas supply as required. An electronic pressure regulator (EPR) 415 is coupled to the supply line 407 downstream of the shut-off valve 410. A pressure sensor 412 is positioned between the shut-off vale 410 and the EPR 415. The EPR 415 receives input from the pressure sensor 412 as to the current pressure in the supply line 407 and is adapted to modify the pressure of the gas being delivered to the paddle apparatus 110 depending on the type of wafer being handled. The EPR 415 can set the nitrogen pressure relatively high for large, heavy wafers, and can set the nitrogen pressure relatively low for smaller, lighter wafers. The EPR 415 may include a programmable processor and memory for storing executable software instructions for controlling the pressure. The pressure can be modified using either open loop or closed loop control. A filter 420 is positioned downstream from the EPR 415 to remove any impurities from the nitrogen gas supply to ensure that the nitrogen gas to which the wafer contains as few impurities as possible. Nitrogen gas exiting the filter 420 reaches an electronically-controlled shut off valve 425 adapted to automatically turn the nitrogen supply on or off. In some implementations, the valve is set to be open normally so that, in the event of an electrical power loss, nitrogen is still supplied to the paddle apparatus to avoid damage to the wafers. Additionally, for the same reason, the EPR 415 can be set so that any configuration settings are retained in the event of power loss.

In operation, when nitrogen gas is supplied to the Bernoulli nozzles of the supporting apparatus, a high-speed radial flow of gas is generated, creating a lower pressure region. The low pressure provides an attractive lift force which causes wafers place on the supporting surface to adhere. Since the walls of the mount at the flange are positioned above the nozzle surface, nitrogen gas that exits the nozzle is forced through a small gap between the mount flange and the wafer, which generates a counteracting repulse force tending to push the wafer away from the nozzle. Pressure regulation allows a balance to be achieved between the lift and repulsion, enabling the wafer to float in place a small gap distance from the supporting surface.

In the embodiments depicted, several nozzles are installed on a single paddle apparatus for handling wafers. The apparatus can be actuated such that wafers can be picked up from below, with the nozzles underneath the wafer, and then flipped over with the wafer in it, allowing the wafer to be put down with the nozzles on the top side of the wafer. In this way, the apparatus allows both sides of the wafer to be processed conveniently.

The combination of the movable grippers and stationary retainers prevent wafers from floating off the paddle to the sides. The movable grippers are retracted to pick up wafers and then moved gently to rest against the wafer, securing the wafer in place on the supporting surface of the paddle. When secured by the grippers and retainers, the precise location of a retained wafer is defined, which allows the wafer to be accurately moved and positioned.

In addition, the vacuum check channel can be plumbed to a pressure sensor. The pressure read will vary largely between two values, a lower value which indicates that a wafer is positioned above the supporting surface of the paddle, and a higher value indicating that the wafer is absent. The wafer present/absent indication can be used as a control signal for adjusting a robot arm to move, pick up, deploy, and/or put down a wafer in a location in a processing station.

It is to be understood that any structural and functional details disclosed herein are not to be interpreted as limiting the systems 112 and methods, but rather are provided as a representative embodiment and/or arrangement for teaching one skilled in the art one or more ways to implement the methods.

It is to be further understood that like numerals in the drawings represent like elements through the several figures, and that not all components and/or steps described and illustrated with reference to the figures are required for all embodiments or arrangements

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing and are not to be construed as limiting. However, it is recognized these terms could be used with reference to a viewer. Accordingly, no limitations are implied or to be inferred.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

While the invention has been described with reference to exemplary embodiments, it will be understood by those skilled in the art that various changes can be made and equivalents can be substituted for elements thereof without departing from the scope of the invention. In addition, many modifications will be appreciated by those skilled in the art to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. An apparatus for supporting and maneuvering a wafer comprising:
a handle section including a gas inlet adapted to couple to a gas supply;
a supporting surface coupled and adjacent to the handle section including a frame structure having a plurality of edge segments connecting to one another at vertices and a plurality of spoke elements extending from a center of the frame structure to the vertices;
a gas supply channel coupled to the gas inlet that extends from the handle and branches into channels that run through the plurality of spoke elements; and
a plurality of nozzles positioned at the vertices on the supporting surface and coupled to the gas supply channel via the channels in the spoke elements;
wherein gas provided to the plurality of nozzles exits the nozzles in a high-speed stream directed parallel to the supporting surface; and
wherein the stream of gas generates attractive and repulsive forces enabling a wafer to be securely supported in a floating manner over the supporting surface without coming into direct contact with the supporting surface or the plurality of nozzles.

2. The apparatus of claim 1, further comprising a vacuum check port positioned in the handle and a vacuum check circuit that extends from the vacuum check port through the edge segments of the supporting surface frame structure to the plurality of nozzles, wherein the vacuum check circuit enables detection of whether a wafer is being supported by the supporting surface.

3. The apparatus of claim 2, further comprising at least one restraining device adapted prevent a supported wafer from moving laterally in a plane parallel to the supporting surface.

4. The apparatus of claim 3, wherein the at least one restraining device includes movable grippers coupled to the handle and stationary retainers coupled to an end of the supporting surface.

5. The apparatus of claim 1, wherein the gas supply provides a supply of nitrogen gas.

6. The apparatus of claim 1, wherein each of the plurality of nozzles include an annular top plate joined to a bottom plate, the bottom plate having a set of holes coupled to a respective spoke channel that are configured to force supplied gas through an interface between the outer rim of the top plate and the bottom plate.

7. The apparatus of claim 6, wherein the annular top plate has a width less than a width of the bottom plate such that a peripheral edge of the top plate is spaced radially inward from a peripheral edge of the bottom plate, the set of holes comprising through holes formed completely through the bottom plate and a center hole is formed through both the bottom plate and the top plate.

8. The apparatus of claim 7, wherein the set of holes are formed circumferentially around the center hole.

9. The apparatus of claim 6, wherein each vertice has a mount that includes a recessed portion that receives one respective nozzle so that the nozzle lies in a plane of a top surface of the mount or below the plane.

10. The apparatus of claim 6, wherein the top plate is welded to the bottom plate with the interface permitting the force supplied gas to flow through the weld along an underside of the top plate in a lateral direction toward a peripheral edge of the bottom plate.

11. The apparatus of claim 2, wherein each nozzle includes a center hole that is axially aligned with a vertical check port formed in a mount at a respective vertice and being part of the vacuum check circuit, the nozzle being securely coupled to the mount.

12. The apparatus of claim 1, wherein the gas supply channel is in fluid communication with an annular shaped channel formed in a hub at the center of the frame structure, the annular shaped channel being in fluid communication with the channels that run through the plurality of spoke elements.

13. An apparatus for supporting and maneuvering a wafer and permitting the wafer to be turned upside down while being transported comprising:
a handle section including a gas inlet adapted to couple to a gas supply;
a supporting surface coupled and adjacent to the handle section including a frame structure;
a gas supply channel coupled to the gas inlet that extends from the handle and branches into channels that run through the frame structure; and
a plurality of nozzles positioned on the supporting surface and coupled to the gas supply channel via the channels in frame structure;
a vacuum check port positioned in the handle and a vacuum check circuit that extends from the vacuum check port through the frame structure to the plurality of nozzles, wherein the vacuum check circuit enables detection of whether a wafer is being supported by the supporting surface;
wherein gas provided to the plurality of nozzles exits the nozzles in a high-speed stream directed parallel to the supporting surface; and
wherein the stream of gas generates attractive and repulsive forces enabling a wafer to be securely supported in a floating manner over the supporting surface without coming into direct contact with the supporting surface or the plurality of nozzles.

14. A system for supporting and maneuvering a wafer comprising:
an apparatus for supporting and maneuvering the wafer including:
a handle section including a gas inlet adapted to couple to a gas supply;
a supporting surface coupled and adjacent to the handle section including a frame structure having a plurality of edge segments connecting to one another at vertices and a plurality of spoke elements extending from a center of the frame structure to the vertices; a gas supply channel coupled to the gas inlet that extends from the handle and branches into channels that run through the plurality of spoke elements; and
a plurality of nozzles positioned at the vertices on the supporting surface and coupled to the gas supply channel via the channels in the spoke elements, the plurality of nozzles providing a high-speed stream directed parallel to the supporting surface; and
a control sub-system positioned between the gas supply and the apparatus and adapted to regulate a pressure supplied to the apparatus based on a size of the wafer.

15. The system of claim 14, wherein the control sub-system includes:
a pressure sensor coupled to the gas supply and adapted to determine a current gas pressure of the gas supply; and
an electronic pressure regulator coupled to the pressure sensor and adapted to receive pressure data from the pressure sensor and to modify the pressure of gas received from the gas supply based on the pressure data and the size of the wafer to be supported.

16. The system of claim 15, wherein the control sub-system further includes a filter positioned downstream from the electronic pressure regulator for removing impurities from the gas supply before the gas reaches the apparatus.

17. The system of claim 14, wherein the gas supply provides a supply of nitrogen gas.

18. The system of claim 14, wherein the frame structure has a hexagon shape.

19. The system of claim 14, wherein the gas supply channel leads to a hub at the center of the frame structure and then branches into the channels that run through the plurality of spoke elements.
